(19) United States
(12) Patent Application Publication
(10) Pub. No.: US 2013/0083600 A1
(43) Pub. Date: Apr. 4, 2013

(54) SEMICONDUCTOR DEVICE AND METHOD OF OPERATING THE SAME

(71) Applicant: Jin Haeng Lee, Seoul (KR)

(72) Inventor: Jin Haeng Lee, Seoul (KR)

(73) Assignee: SK hynix Inc., Icheon-si (KR)

(21) Appl. No.: 13/619,122

(22) Filed: Sep. 14, 2012

(30) Foreign Application Priority Data
Sep. 29, 2011 (KR) 10-2011-0099086

(51) Int. Cl. G11C 16/10; G11C 16/04

(52) U.S. Cl. 365/185.12; 365/185.11; 365/185.18

(57) ABSTRACT

A method of operating a semiconductor device includes selecting one of a plurality of memory cell blocks included in a memory cell array, programming even-numbered memory cells coupled to a selected word line among the word lines of the selected memory cell block, programming odd-numbered memory cells coupled to the selected word line, programming odd-numbered memory cells coupled to a next word line adjacent to the selected word line, and programming even-numbered memory cells coupled to the next word line, wherein the programming is repeated until programming on selected memory cells coupled to all the word lines of the selected memory cell block is completed.

### CROSS-REFERENCE TO RELATED APPLICATION

Priority is claimed to Korean patent application number 10-2011-0099086 filed on Sep. 29, 2011, the entire disclosure of which is incorporated herein by reference in its entirety.

### BACKGROUND

Embodiments of the present invention relate generally to a semiconductor device and methods of operating the same, and more particularly to program methods capable of improving the reliability of a semiconductor device.

A semiconductor device includes a plurality of memory cell arrays for storing data. For fabricating small and high-density semiconductor devices, the number of memory cells in the memory cell arrays is increased and a distance between adjacent memory cells is decreased. This causes interference between adjacent memory cells and thus the reliability of the semiconductor device may deteriorate.

FIG. 1 is a diagram illustrating interference between adjacent memory cells when a known program operation is performed.

Referring to FIG. 1, a memory cell array 10 includes memory cell blocks each including a plurality of cell strings STe and STo. A portion of the memory cell blocks is shown in FIG. 1, for convenience of description. The memory cell block includes a plurality of cell strings STe and STo, and each of the cell strings STe and STo includes a plurality of memory cells that are coupled in series. The even-numbered strings of the cell strings STe and STo are called even strings STe, and the odd-numbered strings thereof are called odd strings STo. Furthermore, a group of memory cells that are included in different cell strings STe and STo and are coupled to the same word line is called a page. A program operation is sequentially performed on pages N−2, N−1, N, N+1, N+2, . . . .

The program operation is described below.

After the program operation is performed on the even-numbered strings STe of an (N−2)^{th} page, the program operation is performed on the odd-numbered strings STo of the (N−2)^{th} page. When both the program operations on the even-numbered and odd-numbered strings STe and STo of the (N−2)^{th} page are completed, the program operation is performed on the even-numbered strings STe of an (N−1)^{th} page, that is, a next page, and is then performed on the odd-numbered strings STo of the (N−1)^{th} page. When the program operations are performed as described above, memory cells included in the even-numbered strings STe of all the (N−2)^{th} to (N+2)^{th} pages are first programmed and memory cells included in the odd-numbered strings STe of all the (N−2)^{th} to (N+2)^{th} pages are then programmed. Accordingly, the memory cells included in the even-numbered strings STe are subject to interference in an X-axis direction when the program operation is performed on the memory cells included in the odd-numbered strings STo adjacent to the even-numbered strings STe and are also subject to interference in a Y-axis direction when the program operation is performed on the memory cells included in a next page. In contrast, the memory cells included in the odd-numbered strings STo are subject to interference in the Y-axis direction when the program operation is performed on a next page, but rarely subject to interference only in the X-axis direction. In FIG. 1, ‘X+Y’ and ‘Y’ indicate interference between adjacent memory cells as described above. That is, the memory cells included in the even-numbered strings STe are subject to interference ‘X+Y’, and the memory cells included in the odd-numbered strings STo are subject to only the interference ‘Y’.

FIG. 2 is a graph illustrating threshold voltages according to the known program operation.

Referring to FIG. 2, selected memory cells on which a program operation has been performed have a target threshold voltage distribution Vt if they are not subject to interference when the program operation on adjacent memory cells is performed, but they have a threshold voltage distribution raised by ‘Vy’ or ‘Vx+y’ owing to the interference occurring when the program operation is performed on adjacent memory cells. The case where the threshold voltage distribution increases by ‘Vy’ corresponds to the case where the selected memory cells are subject to only interference ‘Y’, and the case where the threshold voltage distribution increases by ‘Vx+y’ corresponds to the case where the selected memory cells are subject to interference ‘X+Y’.

Read voltages R1 and R2 are set so that they have a margin of a specific level with respect to a threshold voltage distribution of programmed memory cells because the threshold voltage distribution is changed by interference occurring when a program operation on adjacent memory cells is performed as described above. If memory cells having the target threshold voltage distribution Vt between the read voltages R1 and R2 are read, although the threshold voltage distribution of the memory cells increases by ‘Vy’ owing to interference, such as ‘Y’ in FIG. 1, data may be properly read out from the memory cells because the threshold voltage distribution ‘Vy’ is lower than the read voltage R2. If the memory cells are subject to great interference, such as ‘X+Y’ in FIG. 1, and thus the threshold voltage distribution thereof increases by ‘Vx+y’, however, data may not be properly read out from the memory cells because the threshold voltage distribution ‘Vx+y’ may be higher than the read voltage R2 (see 20 in FIG. 2). Accordingly, the reliability of the semiconductor device is deteriorated.

### BRIEF SUMMARY

Embodiments of the present invention relate to program methods capable of improving the reliability of a semiconductor device and read methods of changing read voltages for selected memory cells depending on whether adjacent memory cells have been programmed or not.

In an embodiment of the present invention, a method of operating a semiconductor device includes selecting one of a plurality of memory cell blocks included in a memory cell array, programming even-numbered memory cells coupled to a selected word line among the word lines of the selected memory cell block, programming odd-numbered memory cells coupled to the selected word line, programming odd-numbered memory cells coupled to a next word line adjacent to the selected word line, and programming even-numbered memory cells coupled to the next word line, wherein the programming is repeated until programming on selected memory cells coupled to all the word lines of the selected memory cell block is completed

In an embodiment of the present invention, a method of operating a semiconductor device includes programming even-numbered memory cells coupled to a first word line, programming odd-numbered memory cells coupled to the first word line, programming odd-numbered memory cells coupled to a second word line adjacent to the first word line, programming even-numbered memory cells coupled to the second word line, programming even-numbered memory cells coupled to a third word line adjacent to the second word line, and programming odd-numbered memory cells coupled to the third word line.

In an embodiment of the present invention, a method of operating a semiconductor device includes programming even-numbered memory cells included in an N^{th} page of a plurality of pages included in a selected memory cell block, programming odd-numbered memory cells included in the N^{th} page when the programming on the even-numbered memory cells of the N^{th} page is completed, programming odd-numbered memory cells included in an (N+1)^{th} page adjacent to the N^{th} page when the programming on the odd-numbered memory cells of the N^{th} page is completed, and programming even-numbered memory cells included in the (N+1)^{th} page when the programming on the odd-numbered memory cells of the (N+1)^{th} page is completed.

In an embodiment of the present invention, a method of operating a semiconductor device includes performing a least significant bit (LSB) program operation on a selected page, performing a most significant bit (MSB) program operation on odd-numbered memory cells included in the selected page after performing the MSB program operation on even-numbered memory cells included in the selected page, performing the LSB program operation on a page next to the selected page, performing the MSB program operation on even-numbered memory cells included in the next page after performing the MSB program operation on odd-numbered memory cells included in the next page.

In an embodiment of the present invention, a method of operating a semiconductor device includes performing a least significant bit (LSB) program operation on a selected memory cell block, performing a most significant bit (MSB) program operation on even-numbered memory cells included in a page selected among a plurality of pages included in the selected memory cell block, performing the MSB program operation on odd-numbered memory cells included in the selected page, performing the MSB program operation on odd-numbered memory cells included in a page next to the selected page, and performing the MSB program operation on even-numbered memory cells included in the next page.

In an embodiment of the present invention, a semiconductor device includes a memory cell array configured to include memory cell blocks and flag cell blocks including a plurality of pages, a row decoder coupled to the word lines of the memory cell array, a voltage generator configured to generate driving voltages and transfer the driving voltages to the row decoder, page buffers coupled to the bit lines of the memory cell array, and a controller configured to control the row decoder, the voltage generator, and the page buffers in order to program all selected memory cells included in a memory cell block selected among the memory cell blocks in such a way as to sequentially program even-numbered memory cells and odd-numbered memory cells included in a selected page of pages included in the selected memory cell block and then sequentially program odd-numbered memory cells and even-numbered memory cells included in a page next to the selected page.

### BRIEF DESCRIPTION OF THE DRAWINGS

FIG. 1 is a diagram illustrating interference between adjacent memory cells when a known program operation is performed;

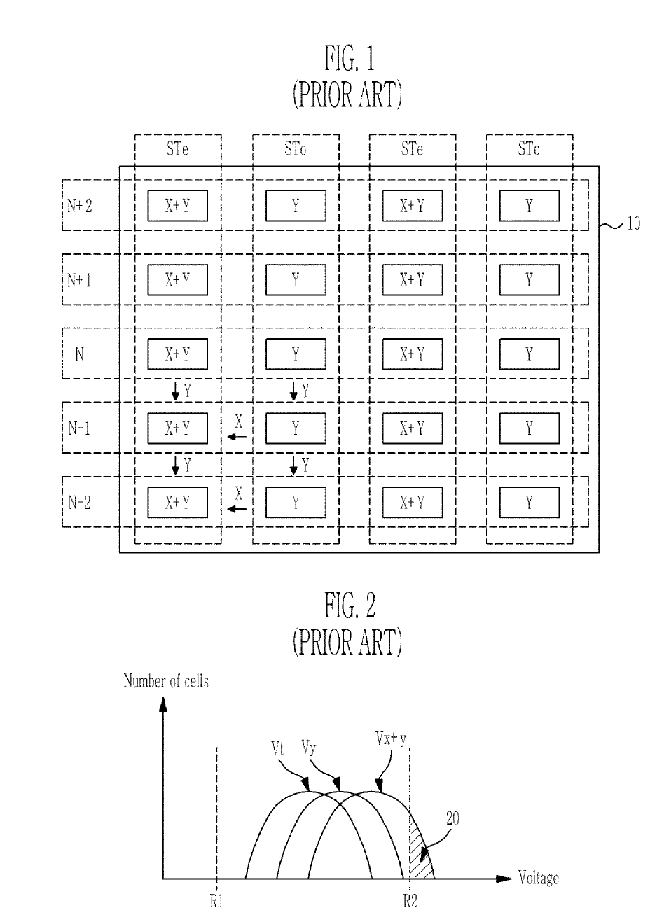

FIG. 2 is a graph illustrating threshold voltages according to the known program operation;

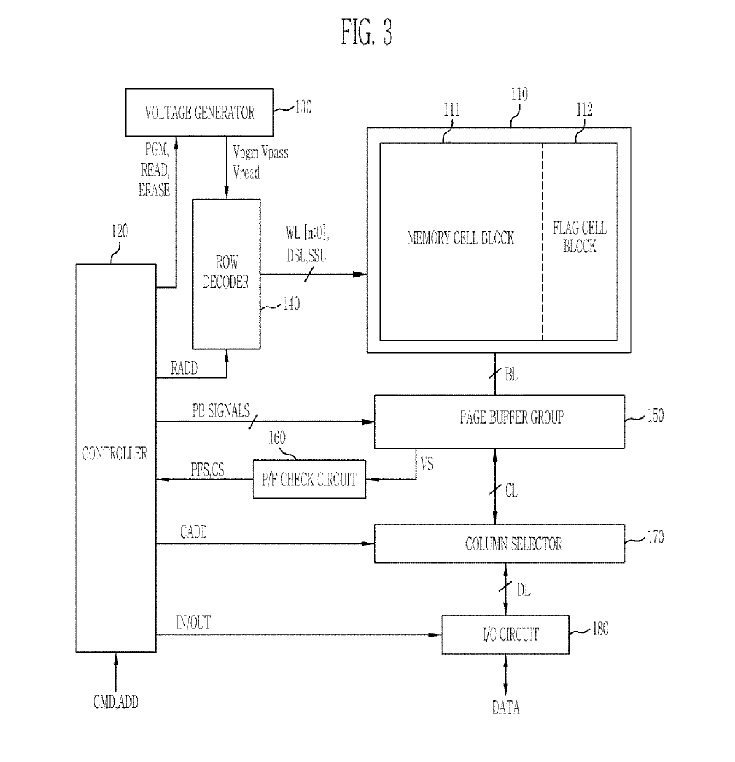

FIG. 3 is a block diagram of a semiconductor device in accordance with an embodiment of the present invention;

FIG. 4 is a detailed circuit diagram of a memory cell array shown in FIG. 3;

FIG. 5 is a flowchart illustrating a program method in accordance with an exemplary embodiment of the present invention;

FIG. 6 is a diagram illustrating interference between memory cells resulting from the program method of FIG. 5;

FIG. 7 is a graph illustrating a shift in the threshold voltages of memory cells due to program operations;

FIG. 8 is a schematic flowchart illustrating a read method in accordance with an exemplary embodiment of the present invention;

FIGS. 9 to 12 are detailed flowcharts illustrating read methods in accordance with some exemplary embodiments of the present invention; and

FIG. 13 is a graph illustrating read voltages used in read operations in accordance with an embodiment of the present invention.

### DESCRIPTION OF EMBODIMENTS

Hereinafter, various embodiments of the present invention are described in detail with reference to the accompanying drawings. The figures are provided to aid those of the ordinary skill in the art to understand the present invention through various embodiments described and shown herein.

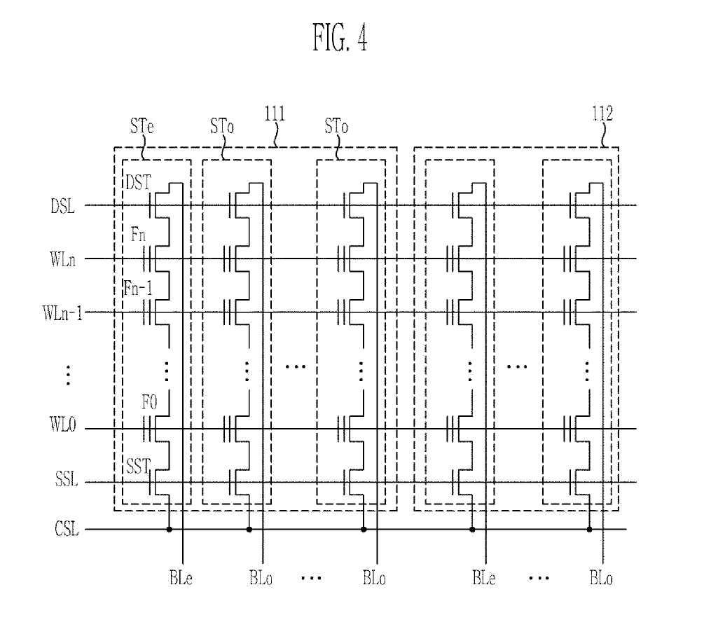

FIG. 3 is a block diagram of a semiconductor device in accordance with an embodiment of the present invention.

Referring to FIG. 3, the semiconductor device includes a memory cell array 110, a plurality of circuits 130, 140, 150, 160, 170, and 180 configured to perform a program, read, or erase operation on memory cells included in the memory cell array 110, and a controller 120 configured to control the plurality of circuits 130, 140, 150, 160, 170, and 180 in order to set the threshold voltages of selected memory cells based on input data.

In case of a NAND flash memory device, the circuits include a voltage generator 130, a row decoder 140, a page buffer group 150, a pass/fail (P/F) check circuit 160, a column selector 170, and an input/output (I/O) circuit 180.

The memory cell array 110 includes a plurality of memory cell blocks. Only one of the memory cell blocks is shown in FIG. 3, for simplicity. Each of the memory cell blocks includes a memory cell block 111 including normal cell strings for storing main data and a flag cell block 112 including flag cell strings for storing extra data necessary for various operations. The normal cell strings and the flag cell strings may have the same configuration as each other although their functions are different from each other. For example, cell strings of the memory cell block 111 and the flag cell block 112 may have the same configuration as each other.

The controller 120 generates a program operation signal PGM, a read operation signal READ, or an erase operation signal ERASE in response to a command signal CMD and also generates page buffer signals PB SIGNALS for controlling the page buffers of the page buffer group 150 depending on the type of operation. Furthermore, the controller 120 generates a row address signal RADD and a column address signal CADD in response to an address signal ADD. The controller 120 checks a P/F signal PFS outputted from the P/F check circuit 160 in a verify operation and determines whether to perform a relevant operation again or not, whether to complete the relevant operation or not, or whether the relevant operation fails or not according to a result of the check. In particular, in a read operation, the controller 120 varies a read voltage for reading out a selected memory cell depending on whether memory cells adjacent to the selected memory cell have been programmed or not.

The voltage generator 130 generates operating voltages (for example, Vpgm, Vread, and Vpass) for programming, reading out, or erasing memory cells to global lines in response to the operation signals PGM, READ, and ERASE, that is, the internal command signals of the controller 120.

The row decoder 140 transfers the operating voltages of the voltage generator 130 to the lines WL[n:0], DSL, and SSL of a selected memory cell block in response to row address signals RADD of the controller 120.

The page buffer group 150 detects the programmed or erased state of memory cells. The page buffer group 150 includes the page buffers coupled to respective bit lines BL and provides voltages necessary to store data in memory cells to the respective bit lines BL in response to page buffer signals PB SIGNALS of the controller 120. Particularly, the page buffer group 150 precharges the bit lines BL when a program operation, an erase operation, or a read operation is performed on memory cells or latches data corresponding to the threshold voltages of memory cells that are detected depending on a change in the voltages of the bit lines BL. That is, when a program operation is performed, each of the page buffers included in the page buffer group 150 applies a program permission voltage 0 V to a relevant bit line BL when program data stored in the latch of the page buffer is 0 and a program inhibition voltage Vcc to the relevant bit line BL when the program data stored in the latch of the page buffer is 1. Furthermore, when a read operation is performed, the page buffers control the voltages of the bit lines BL in response to data stored in the memory cells and detect data stored in the memory cells based on the controlled voltages. In addition, when a verify or read operation is performed, the page buffers sends data VS, detected from the memory cells, to the P/F check circuit 160.

The P/F check circuit 160 generates the P/F signal PFS of a relevant operation in response to the data VS received from the page buffers when a verify operation subsequent to a program or erase operation is performed or checks whether an error cell has occurred or not. Furthermore, the P/F check circuit 160 counts the number of error cells when an error cell occurs and generates a result of the count in the form of a count signal CS.

The column selector 170 selects the page buffers of the page buffer group 150 in response to the column address signal CADD of the controller 120. Data latched in a page buffer selected by the column selector 170 is outputted. Furthermore, the column selector 170 receives data from the page buffer group 150 through a column line CL and transfers the data to the I/O circuit 180.

The I/O circuit 180 transfers external data DATA to the column selector 170 in response to the input/output signal IN/OUT of the controller 120 when a program operation is performed so that the data DATA are inputted to the page buffers of the page buffer group 150. When the column selector 170 transfers the external data DATA to the page buffers of the page buffer group 150, the page buffers store the received data in their latches. Furthermore, when a read operation is performed, the I/O circuit 180 outputs data DATA, received from the page buffers of the page buffer group 150, through the column selector 170 in response to the I/O signal IN/OUT of the controller 120.

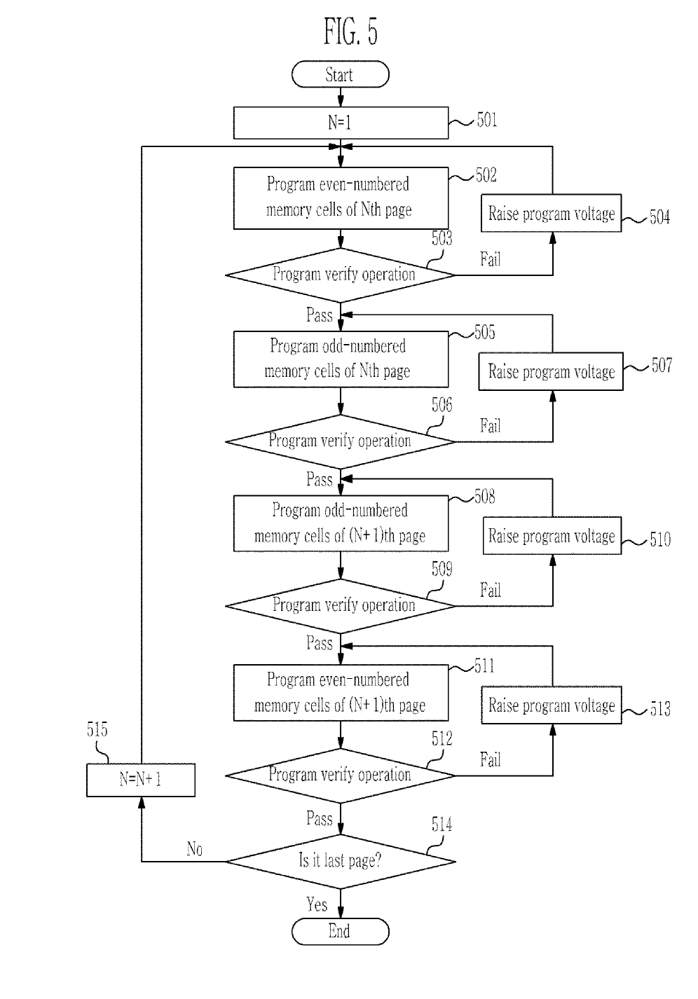

FIG. 4 is a detailed circuit diagram of the memory cell array 110 shown in FIG. 3.

Referring to FIG. 4, the cell strings ST included in the memory cell block 111 and the flag cell block 112 of the memory cell array 110 have the same configuration. One of the cell strings STe included in the memory cell block 111 is described below as an example. The cell string STe includes a source select transistor SST coupled to a common source line CSL, a plurality of memory cells F0 to Fn, and a drain select transistor DST coupled to a bit line BLe. Cells included in a flag cell string are called flag cells, but they may have the same configuration as the normal memory cell. The gate of the source select transistor SST is coupled to a source select line SSL, the gates of the memory cells F0 to Fn are coupled to respective word lines WL0 to WLn, and the gate of the drain select transistor DST is coupled to a drain select line DSL. The cell strings ST are coupled between the common source line CSL and the respective bit lines BLe and BLo corresponding to the cell strings ST. Even-numbered bit lines are called even bit lines BLe and odd-numbered bit lines are called odd bit line BLo depending on order of the arrangement of the bit lines. Accordingly, the cell strings coupled to the even bit lines BLe are called even strings STe, and cell strings coupled to the odd bit lines BLo are called odd strings STo.

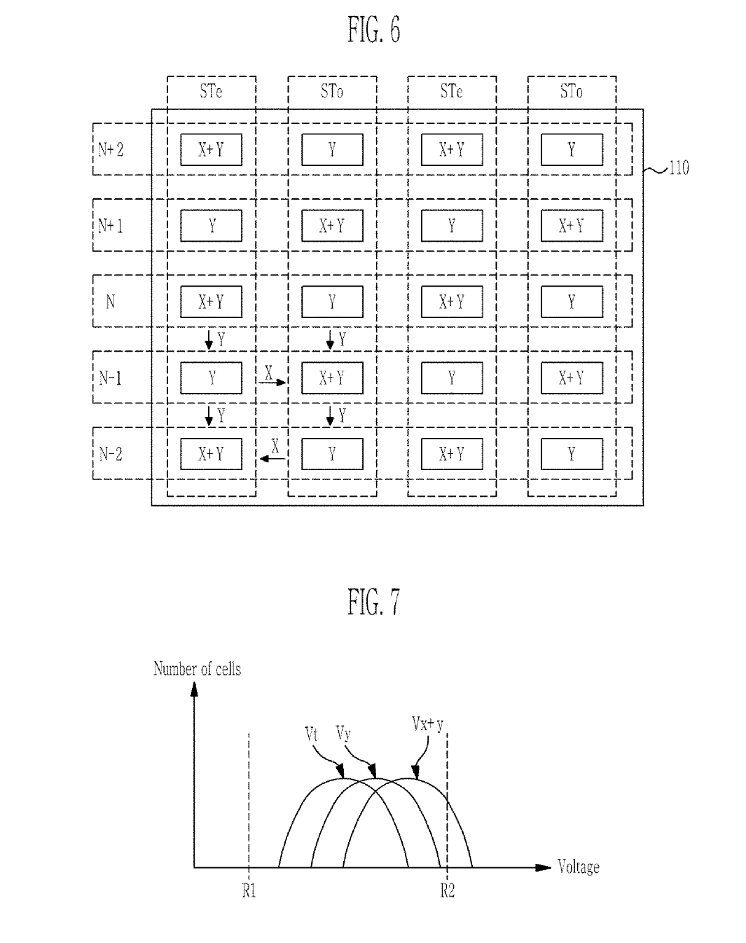

FIG. 5 is a flowchart illustrating a program method in accordance with an exemplary embodiment of the present invention.

A program operation on a single level cell (hereinafter referred to as SLC) or a most significant bit (hereinafter referred to as MSB) program operation on a multi-level cell (hereinafter referred to as MLC) are described below with reference to FIG. 5. In case of an MLC, after a least significant bit (hereinafter referred to as LSB) program operation on a selected memory cell block is completed, an MSB program operation may be performed. In some embodiments, after an LSB program operation is performed on a selected page when a page is selected in a selected memory cell block, an MSB program operation may be performed on the selected page.

When a program routine is started, one memory cell block is selected in response to a row address, and one of a plurality of pages included in the selected memory cell block is selected. If the order of the pages is indicated by N, the order N of a first selected page is 1 (that is, N=1) at step 501.

A program operation is performed on the even-numbered memory cells of the N^{th} page at step 502. The program operation is performed according to an incremental step pulse program (ISPP) method of raising a program voltage gradually. Particularly, in order to perform the program operation on selected memory cells included in the even strings STe, from among the memory cells of the N^{th} page, the program voltage is supplied to a selected word line coupled to the N^{th} page so that the threshold voltages of the selected memory cells increase.

Next, a program verify operation is performed on the even-numbered memory cells of the N^{th} page at step 503. The program verify operation is performed in order to verify whether all the threshold voltages of the even-numbered memory cells of the N^{th} page have reached a target level. If a result of the program verify operation is a failure, the program voltage supplied to the selected word line coupled to the N^{th} page is raised at step 504, and the program operation is performed on the even-numbered memory cells of the N^{th} page again at step 502. The steps 502 to 504 are repeated until all the threshold voltages of the even-numbered memory cells of the N^{th} page reach the target level. When all the threshold voltages of the even-numbered memory cells of the N^{th} page reach the target level, a result of the program verify operation at step 503 is a pass.

If a result of the program verify operation on the even-numbered memory cells of the N^{th} page at step 503 is a pass, a program operation is performed on the odd-numbered memory cells of the N^{th} page at step 505. The program operation is performed according to an incremental step pulse program (ISPP) method of raising a program voltage gradually. Particularly, in order to perform the program operation on selected memory cells included in the odd strings STe, from among the memory cells of the N^{th} page, a program voltage is supplied to the selected word line coupled to the N^{th} page so that the threshold voltages of the selected memory cells increase.

A program verify operation is performed on the odd-numbered memory cells of the N^{th} page at step 505. The program verify operation is performed in order to verify whether all the threshold voltages of the odd-numbered memory cells of the N^{th} page have reached the target level.

If a result of the program verify operation is a failure, the program voltage supplied to the selected word line coupled to the N^{th} page is raised at step 507, and the program operation is performed on the odd-numbered memory cells of the N^{th} page again at step 505. The steps 505 to 507 are repeated until all the threshold voltages of the odd-numbered memory cells of the N^{th} page reach the target level. When all the threshold voltages of the odd-numbered memory cells of the N^{th} page reach the target level, a result of the program verify operation at step 505 is a pass.

When the program and program verify operations on the selected memory cells included in the N^{th} page are completed, a program operation is performed on the odd-numbered memory cells of an (N+1)^{th} page, that is, a next page at step 508. Particularly, in order to perform the program operation on selected memory cells included in the odd strings STo, from among the memory cells of the (N+1)^{th} page, a program voltage is supplied to a selected word line coupled to the (N+1)^{th} page so that the threshold voltages of the selected memory cells increase.

Next, a program verify operation is performed on the odd-numbered memory cells of the (N+1)^{th} page at step 509. The program verify operation is performed in order to verify whether all the threshold voltages of the odd-numbered memory cells of the (N+1)^{th} page have reached the target level. If a result of the program verify operation is a failure, the program voltage supplied to the selected word line coupled to the (N+1)^{th} page is raised at step 510, and the program operation is performed on the odd-numbered memory cells of the (N+1)^{th} page again at step 508. The steps 508 to 510 are repeated until all the threshold voltages of the odd-numbered memory cells of the (N+1)^{th} page reach the target level. When all the threshold voltages of the odd-numbered memory cells of the (N+1)^{th} page reach the target level, a result of the program verify operation 509 is a pass.

When a result of the program verify operation on the odd-numbered memory cells of the (N+1)^{th} page at step 509 is a pass, a program operation is performed on the even-numbered memory cells of the (N+1)^{th} page at step 511. Particularly, in order to perform the program operation on selected memory cells included in the even string STe, from among the memory cells of the (N+1)^{th} page, a program voltage is supplied to a selected word line coupled to the (N+1)^{th} page so that the threshold voltages of the selected memory cells increase.

Next, a program verify operation is performed on the even-numbered memory cells of the (N+1)^{th} page at step 512. The program verify operation is performed in order to verify whether all the threshold voltages of the even-numbered memory cells of the (N+1)^{th} page have reached the target level. If a result of the program verify operation is a failure, the program voltage supplied to the selected word line coupled to the (N+1)^{th} page is raised at step 513, and the program operation is performed on the even-numbered memory cells of the (N+1)^{th} page again at step 511. The steps 511 to 513 are repeated until all the threshold voltages of the even-numbered memory cells of the (N+1)^{th} page reach the target level. When all the threshold voltages of the even-numbered memory cells of the (N+1)^{th} page reach the target level, a result of the program verify operation at step 512 is a pass.

When the program and program verify operations on the selected memory cells included in the (N+1)^{th} page are completed, whether the (N+1)^{th} page is the last page of the selected memory cell block is determined at step 514. If, as a result of the determination, it is determined that the (N+1)^{th} page is not the last page of the selected memory cell block, the address of the page is, for example, increased by 1 (that is, N=N+1) in order to select a next page at step 515. Next, the steps 502 to 514 are repeated until program and program verify operations on the selected memory cells of the remaining pages are completed. If, as a result of the determination at step 514, it is determined that a programmed page is the last page of the selected memory cell block, the program routine for the selected memory cell block is terminated.

If a program operation is performed as described above, each of memory cells included in the same page is subject to different interference, and each of memory cells included in the same cell string is also subject to different interference. Interference between the memory cells resulting from the above-described program operation is described below.

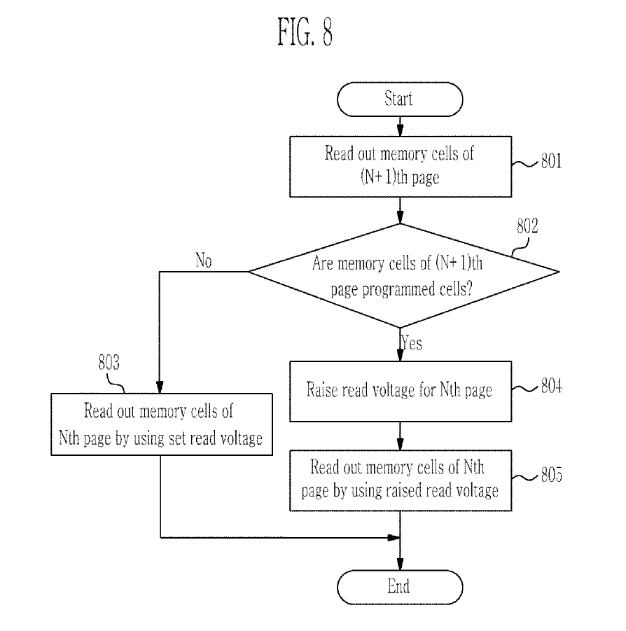

FIG. 6 is a diagram illustrating interference between memory cells resulting from the program method of FIG. 5.

Referring to FIG. 6, if even-numbered and odd-numbered memory cells included in an N^{th} page are sequentially programmed and odd-numbered and even-numbered memory cells included in an (N+1)^{th} page are sequentially programmed as described above with reference to FIG. 5, each of memory cells adjacent to the N^{th} page and the (N+1)^{th} page is subject to different interference. For example, when even-numbered memory cells included in the even strings STe of an (N−2)^{th} page are programmed and odd-numbered memory cells included in the odd strings STo of the (N−2)^{th} page are then programmed, the even-numbered memory cells included in the (N−2)^{th} page are subject to interference in the X-axis direction. Next, when odd-numbered memory cells included in an (N−1)^{th} page, that is, a next page, are programmed, the odd-numbered memory cells of the N^{th} page are also subject to interference in the Y-axis direction.

When even-numbered memory cells included in the (N−1)^{th} page are programmed, the even-numbered memory cells of the N^{th} page are also subject to interference in the Y-axis direction. If a program operation is performed as described above, the even-numbered memory cells included in the even strings STe of the (N−2)^{th} page are subject to interference ‘X+Y’, and the odd-numbered memory cells included in the odd strings STo of the (N−2)^{th} page are subject to interference ‘Y’. Furthermore, the even-numbered memory cells included in the even strings STe of the (N−1)^{th} page are subject to interference ‘Y’, and the odd-numbered memory cells included in the odd strings STo of the (N−1)^{th} page are subject to interference ‘X+Y’. That is, even-numbered memory cells and odd-numbered memory cells included in the same page are alternately subject to the interference ‘X+Y’ and the interference ‘Y’. Memory cells included in different pages within the same cell string are also alternately subject to the interference ‘X+Y’ and the interference ‘Y’. The threshold voltages of the memory cells subjected to the interference ‘X+Y’ have a relatively lower increment than those of the memory cells subjected to only the interference ‘Y’.

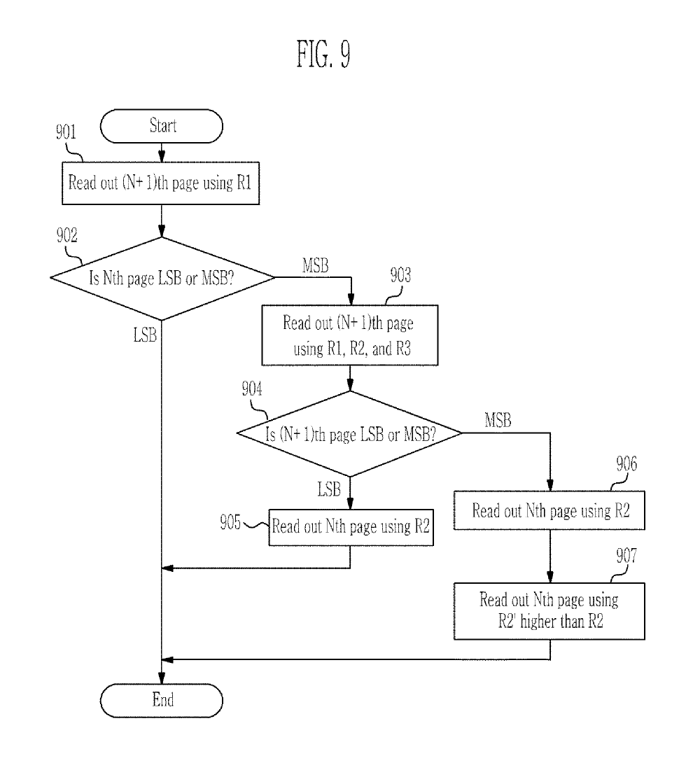

FIG. 7 is a graph illustrating a shift in the threshold voltages of memory cells due to program operations.

Referring to FIG. 7, a target threshold voltage distribution Vt of programmed memory cells is placed between a first read voltage R1 and a second read voltage R2. However, the target threshold voltage distribution Vt increase by a certain level owing to interference occurring when a program operation is performed on memory cells adjacent to the programmed memory cells. As described above with reference to FIG. 6, in general, a threshold voltage distribution Vy raised by interference ‘Y’ does not become higher than the second read voltage R2. This is because the second read voltage R2 is set considering a shift in the threshold voltages due to the interference ‘Y’. If the programmed memory cells are subject to the interference ‘X+Y’ greater than the interference ‘Y’, however, the threshold voltages of the programmed memory cells further increase to a higher level (e.g., Vx+y), and the threshold voltages of some programmed memory cells may become higher than the second read voltage R2. If the threshold voltages of programmed memory cells increase as described above, a read operation is performed as follows.

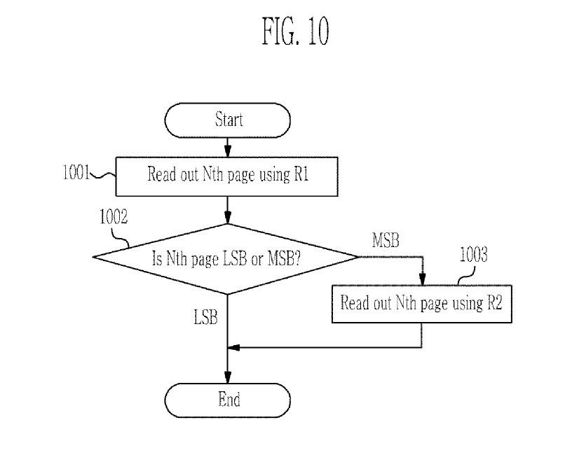

FIG. 8 is a schematic flowchart illustrating a read method in accordance with an exemplary embodiment of the present invention.

Referring to FIG. 8, before reading out selected memory cells, data are read out from memory cells adjacent to the selected memory cells in order to obtain information about interference at the selected memory cells and data are read out from the selected memory cells using a read voltage varied according to the information. This process is described in detail below.

Before reading out data from memory cells included in a selected N^{th} page, data are read out from memory cells included in an (N+1)^{th} page, that is, a next page, at step 801. Whether the read memory cells of the (N+1)^{th} page are programmed memory cells or not is determined at step 802. If, as a result of the determination, it is determined that the memory cells of the (N+1)^{th} page are not programmed memory cells, data are read out from the memory cells of the (N+1)^{th} page at step 803 using a preset read voltage. If, as a result of the determination at step 802, it is determined that the memory cells of the (N+1)^{th} page are programmed memory cells, a read voltage for the N^{th} page is raised by a certain level at step 804. Data are read out from the memory cells of the N^{th} page at step 805 using the raised read voltage. If, as described above, a read voltage for reading out selected memory cells is varied depending on whether adjacent memory cells have been programmed, the reliability of data read from the selected memory cells can be improved.

If a program operation is performed as described above, a maximum interference that may occur in each of memory cells can be known. Accordingly, a read operation can be performed according to an algorithm corresponding to selected memory cells. For example, referring to FIG. 6, since the memory cells included in the even strings STe of the (N−2)^{th} page may be subject to the maximum interference ‘X+Y’, a relevant read operation may be performed. Furthermore, since the memory cells included in the odd strings STo of the (N−2)^{th} page may be subject to the maximum interference ‘Y’, a relevant read operation may be performed.

Methods of reading out programmed memory cells according to the above program method are described in detail below.

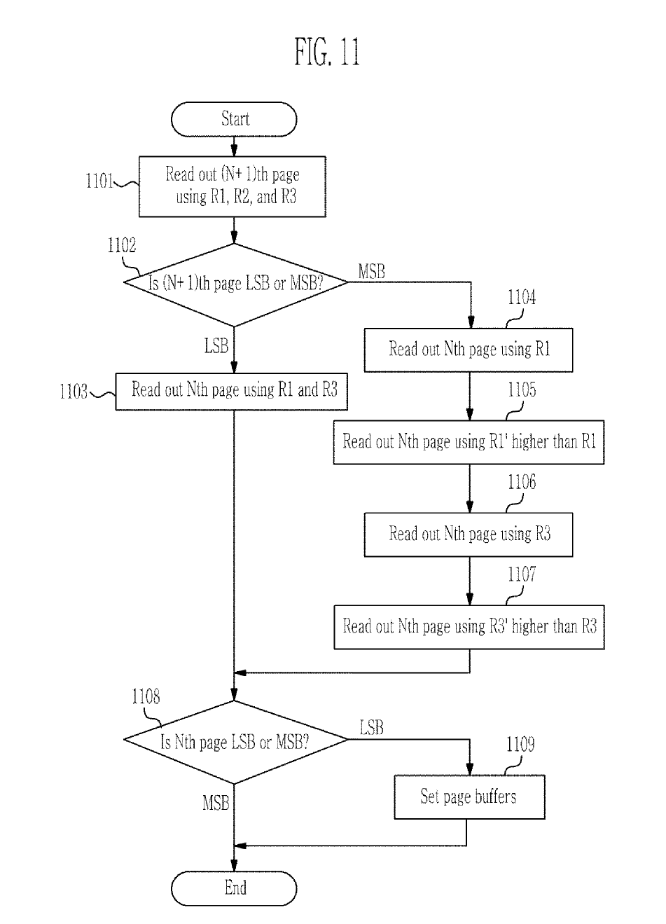

FIGS. 9 to 12 are detailed flowcharts illustrating read methods in accordance with some exemplary embodiments of the present invention. It is hereinafter assumed that an N^{th} page is a selected page.

FIG. 9 is a flowchart illustrating the LSB read method of memory cells that may be subject to the interference ‘X+Y’.

Referring to FIG. 9, data are read from memory cells included in the N^{th} page by using a first read voltage R1 at step 901. The read data are stored in the latches of page buffers. Next, whether the N^{th} page is an LSB-programmed page or an MSB-programmed page is determined at step 902. In order to determine whether the N^{th} page is the LSB-programmed page or the MSB-programmed page, data are read from the flag cells of the Nth page. That is, after an MSB program operation is performed on each page, data ‘0’ is programmed in the flag cells of each page. Thus, whether the page has been subject to an LSB program or an MSB program can be determined by reading the data of the flag cells. For example, if data read from flag cells is ‘0’, it means that a relevant page is an MSB-programmed page. For example, if data read from flag cells is ‘1’, it means that a relevant page is an LSB-programmed page or a page in an erased state. If, as a result of the determination at step 902, it is determined that the N^{th} page is an LSB-programmed page, the data read at step 901 is outputted, and the read operation is terminated. If, as a result of the determination at step 902, it is determined that the N^{th} page is an MSB-programmed page, a read operation is performed on an (N+1)^{th} page, that is, a next page, at step 903. The read operation on the (N+1)^{th} page is performed using the first read voltage R1, a second read voltage R2, and a third read voltage R3. The second read voltage R2 is higher than the first read voltage R1, and the third read voltage R3 is higher than the second read voltage R2. Next, whether the (N+1)^{th} page is an LSB-programmed page or an MSB-programmed page is determined at step 904. In order to determine whether the (N+1)^{th} page is an LSB-programmed page or an MSB-programmed page, data are read from the flag cells of the (N+1)^{th} page. For example, if the data read from the flag cells is ‘0’, it means that the (N+1)^{th} page is an MSB-programmed page. For example, if the data read from the flag cells is ‘1’, it means that the (N+1)^{th} page is an LSB-programmed page or a page in an erased state. If, as a result of the determination at step 904, it is determined that the (N+1)^{th} page is a page on which only an LSB program has been performed, an LSB read operation is performed on the N^{th} page by using the second read voltage R2 at step 905. If, as a result of the determination at step 904, it is determined the (N+1)^{th} page is a page on which up to an MSB program has been performed, an LSB read operation is performed on the N^{th} page by using the second read voltage R2 because the N^{th} page may be subject to interference at step 906. Next, an LSB read operation is performed on the N^{th} page by using a second variable voltage R2′ higher than the second read voltage R2 at step 907. Here, the LSB read operation performed on the N^{th} page by using the second read voltage R2 at step 906 may be omitted because it is performed in order to read data from memory cells less subject to interference, from among memory cells included in the N^{th} page. For example, the step 906 may be performed in order to read data from memory cells when there is interference ‘Y’. If an MSB program has been performed on adjacent memory cells as in step 907, data are read from selected memory cells by using the second variable voltage R2′ higher than the second read voltage R2 because the threshold voltages of the selected memory cells increase. If, as described above, a read voltage for reading out selected memory cells is determined depending on the state of adjacent memory cells, e.g., threshold voltages of adjacent memory cells, data in the selected memory cells can be correctly read out even when the threshold voltages of the selected memory cells are shifted.

FIG. 10 is a flowchart illustrating the LSB read method of memory cells that may be subject to the interference ‘Y’.

Referring to FIG. 10, data are read from memory cells included in the N^{th} page by using the first read voltage R1 at step 1001. The read data are stored in the latches of respective page buffers. Next, whether the N^{th} page is an LSB-programmed page or an MSB-programmed page is determined at step 1002. In order to determine whether the N^{th} page is an LSB-programmed page or an MSB-programmed page, data are read from the flag cells of the N^{th} page. For example, if the data read from the flag cells is ‘0’, it means that the (N+1)^{th} page is an MSB-programmed page. For example, if the read data is ‘1’, it means that the (N+1)^{th} page is an LSB-programmed page or a page in an erased state. If, as a result of the determination at step 1002, it is determined the N^{th} page is an LSB-programmed page, the data read at step 1001 is outputted, and the read operation is terminated. If, as a result of the determination at step 1002, it is determined the N^{th} page is an MSB-programmed page, an LSB read operation is performed on the N^{th} page by using the second read voltage R2 at step 1003, and the read operation is terminated.

FIG. 11 is a flowchart illustrating the MSB read method of memory cells that may be subject to the interference ‘X+Y’.

Referring to FIG. 11, data are read from memory cells included in the (N+1)^{th} page, that is, a page next to the N^{th} page at step 1101. For example, the read operation may be performed using the first read voltage R1, the second read voltage R2, and the third read voltage R3. When data are read out from the memory cells, threshold voltages of the memory cells are checked using the first to third read voltages R1 to R3. Whether the memory cells of the (N+1)^{th} page are LSB-programmed memory cells or MSB-programmed memory cells is determined at step 1102 based on a result of the read operation for the (N+1)^{th} page performed at step 1101. In order to determine whether the (N+1)^{th} page is an LSB-programmed page or an MSB-programmed page, data are read from the flag cells of the (N+1)^{th} page. For example, if the data read from the flag cells is ‘0’, it means that the (N+1)^{th} page is an MSB-programmed page. For example, if the data read from the flag cells is ‘1’, it means that the (N+1)^{th} page is an LSB-programmed page or a page in an erased state. If, as a result of the determination at step 1102, it is determined that the (N+1)^{th} page is an LSB-programmed page, data are read out from the memory cells of the N^{th} page using the first read voltage R1 and the third read voltage R3. If, as a result of the determination at step 1102, it is determined that the (N+1)^{th} page is an MSB-programmed page, data are read out from the memory cells of the N^{th} page at step 1104 using the first read voltage R1. The read operation using the first read voltage R1 is performed so as to read out correct data from memory cells of the N^{th} page having threshold voltages slightly shifted by interference. Accordingly, the step 1104 may be omitted. In order to read out correct data from memory cells of the N^{th} page having their threshold voltages greatly shifted by interference, a read operation is performed on the memory cells of the N^{th} page by using a first variable voltage R1′ higher than the first read voltage R1 at step 1105. Next, data are read out from the memory cells of the N^{th} page at step 1106 using the third read voltage R3. The read operation using the third read voltage R3 is performed so as to read out correct data from memory cells of the N^{th} page having threshold voltages slightly shifted by interference. Accordingly, the step 1106 may also be omitted. In order to read out correct data from memory cells of the N^{th} page having threshold voltages greatly shifted by interference, a read operation is performed on the memory cells of the N^{th} page by using a third variable voltage R3′ higher than the third read voltage R3 at step 1107. After step 1103 and step 1107, whether the N^{th} page is an LSB-programmed page or an MSB-programmed page is determined at step 1108. In order to determine whether the N^{th} page is an LSB-programmed page or an MSB-programmed page, data are read from the flag cells of the N^{th} page. For example, if the data read from the flag cells is ‘0’, it means that the N^{th} N page is an MSB-programmed page. For example, if the data read from the flag cells is ‘1’, it means that the N^{th} page is an LSB-programmed page or a page in an erased state. If, as a result of the determination at step 1108, it is determined that the N^{th} page is an MSB-programmed page, the previously read data are outputted and the read operation is then terminated. If, as a result of the determination at step 1108, it is determined that the N^{th} page is an LSB-programmed page, relevant page buffers are set so that data ‘1’ is inputted to the latches of the relevant page buffers at step 1109. Particularly, although the selected memory cells are illustrated as being subject to an MSB read operation, data ‘1’ indicating an erased state is inputted to the latches of all the page buffers and the read operation is then terminated because the selected memory cells are not MSB-programmed memory cells if they are LSB-programmed memory cells.

FIG. 12 is a flowchart illustrating the MSB read method of memory cells that may be subject to interference ‘Y’.

Referring to FIG. 12, data are read from memory cells included in the N^{th} page by using the first read voltage R1 and the third read voltage R3 at step 1201. The read data are stored in the latches of relevant page buffers. Next, whether the N^{th} page is an LSB-programmed page or an MSB-programmed page is determined at step 1202. In order to determine whether the N^{th} page is an LSB-programmed page or an MSB-programmed page, data are read from the flag cells of the N^{th} page. If the data read from the flag cells is ‘0’, it means that the N^{th} page is an MSB-programmed page. If the data read from the flag cells is ‘1’, it means that the N^{th} page is an LSB-programmed page or a page in an erased state. If, as a result of the determination at step 1202, it is determined that the N^{th} page is an LSB-programmed page, the data read at step 1201 is outputted and the read operation is then terminated. If, as a result of the determination at step 1202, it is determined that the N^{th} page is an MSB-programmed page, relevant page buffers are set so that data ‘1’ is inputted to the latches of the relevant page buffers at step 1203. Particularly, although the selected memory cells are illustrated as being subject to an MSB read operation, data ‘1’ indicating an erased state is inputted to the latches of all the page buffers and the read operation is then terminated because the selected memory cells are not MSB-programmed memory cells if they are LSB-programmed memory cells.

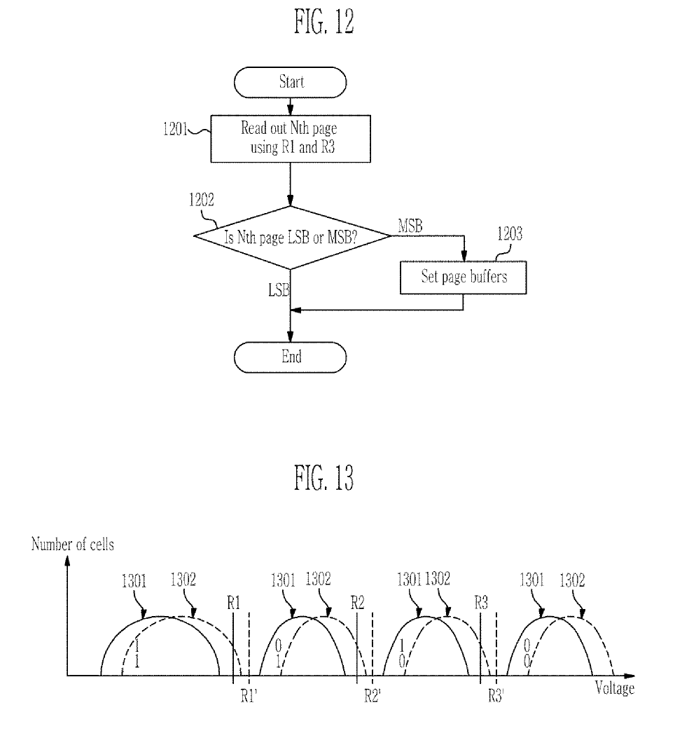

FIG. 13 is a graph illustrating read voltages used in read operations in accordance with an embodiment of the present invention.

Referring to FIG. 13, as described above with reference to FIGS. 9 to 12, the threshold voltage distributions 1301 of memory cells not subjected or slightly subject to interference from adjacent memory cells are not changed or are slightly changed. Accordingly, the read operations on the memory cells are performed by using the first, second, and third read voltages R1, R2, and R3. In contrast, the threshold voltage distributions 1302 of memory cells greatly subjected to interference from adjacent memory cells are greatly changed. Accordingly, the read operations on the memory cells are performed by using the varied read voltages R1′, R2′, and R3′. Accordingly, the reliability of a read operation can be improved.

In accordance with an embodiment of the present invention, the order of program operation on memory cells may be adjusted depending on the state (e.g. threshold voltage) of memory cells adjacent to the selected memory cells, and this may improve the reliability of a read operation.

What is claimed is:

1. A method of operating a semiconductor device, comprising:
selecting one of a plurality of memory cell blocks included in a memory cell array;
programming even-numbered memory cells coupled to a selected word line among word lines of the selected memory cell block;
programming odd-numbered memory cells coupled to the selected word line;
programming odd-numbered memory cells coupled to a next word line adjacent to the selected word line; and
programming even-numbered memory cells coupled to the next word line,
wherein the programming is repeated until programming on selected memory cells coupled to all the word lines of the selected memory cell block is completed.

2. The method of claim 1, wherein programming the even-numbered memory cells coupled to the selected word line comprises:
supplying a program voltage to the selected word line so that threshold voltages of the even-numbered memory cells coupled to the selected word line increase;
determining whether all the threshold voltages of the even-numbered memory cells coupled to the selected word line have reached a target level or not; and
repeatedly programming the even-numbered memory cells coupled to the selected word line while raising the program voltage gradually If, as a result of the determination, it is determined that all the threshold voltages have not reached the target level.

3. The method of claim 1, wherein programming the odd-numbered memory cells coupled to the selected word line comprises:
supplying a program voltage to the selected word line so that threshold voltages of the odd-numbered memory cells coupled to the selected word line increase;
determining whether all the threshold voltages of the odd-numbered memory cells coupled to the selected word line have reached a target level or not; and
repeatedly programming the odd-numbered memory cells coupled to the selected word line while raising the program voltage gradually If, as a result of the determination, it is determined that all the threshold voltages have not reached the target level.

4. The method of claim 1, further comprising:
reading memory cells coupled to the next word line; and
reading memory cells coupled to the selected word line by using a first read voltage when the memory cells coupled to next word line are not programmed and reading the memory cells coupled to the selected word line by using a second read voltage higher than the first read voltage when the memory cells coupled to the next word line are programmed.

5. The method of claim 4, wherein the reading of the memory cells coupled to the next word line comprises:
reading the memory cells coupled to the next word line by using the first read voltage; and
determining whether a least significant bit (LSB) program operation or a most significant bit (MSB) program operation has been performed on the memory cells coupled to the next word line.

6. The method of claim 5, wherein the memory cells coupled to the selected word line are read by using the second read voltage if, as a result of the determination, it is determined that the LSB program operation has been performed on the memory cells coupled to the next word line, and
the memory cells coupled to the selected word line are read by using a third read voltage higher than the second read voltage if, as a result of the determination, it is determined that the MSB program operation has been performed on the memory cells coupled to the next word line.

7. A method of operating a semiconductor device, comprising:
programming even-numbered memory cells coupled to a first word line;
programming odd-numbered memory cells coupled to the first word line;
programming odd-numbered memory cells coupled to a second word line adjacent to the first word line;
programming even-numbered memory cells coupled to the second word line;
programming even-numbered memory cells coupled to a third word line adjacent to the second word line; and
programming odd-numbered memory cells coupled to the third word line.

8. The method of claim 7, further comprising:
reading memory cells coupled to the second word line; and
reading memory cells coupled to the first word line by using a first read voltage when the memory cells coupled to the second word line are not programmed and reading the memory cells coupled to the first word line by using a second read voltage higher than the first read voltage when the memory cells coupled to the second word line are programmed.

9. The method of claim 7, further comprising:
reading memory cells coupled to the third word line; and
reading memory cells coupled to the second word line by using a first read voltage when the memory cells coupled to the third word line are not programmed and reading the memory cells coupled to the second word line by using a second read voltage higher than the first read voltage when the memory cells coupled to the third word line are programmed.

10. A method of operating a semiconductor device, comprising:
programming even-numbered memory cells included in an N^{th} page of a plurality of pages included in a selected memory cell block;
programming odd-numbered memory cells included in the N^{th} page when the programming on the even-numbered memory cells of the N^{th} page is completed;
programming odd-numbered memory cells included in an (N+1)^{th} page adjacent to the N^{th} page when the programming on the odd-numbered memory cells of the N^{th} page is completed; and
programming even-numbered memory cells included in the (N+1)^{th} page when the programming on the odd-numbered memory cells of the (N+1)^{th} page is completed.

11. The method of claim 10, wherein the page is a group of memory cells coupled to an identical word line.

12. The method of claim 10, further comprising:
reading memory cells included in the (N+1)^{th} page; and
reading memory cells included in the N^{th} page by using a first read voltage when the memory cells included in the (N+1)^{th} page are not programmed and reading the memory cells included in the N^{th} page by using a second read voltage higher than the first read voltage when the memory cells included in the (N+1)^{th} page are programmed.

13. A method of operating a semiconductor device, comprising:
performing a least significant bit (LSB) program operation on a selected page;
performing a most significant bit (MSB) program operation on odd-numbered memory cells included in the selected page after performing the MSB program operation on even-numbered memory cells included in the selected page;
performing the LSB program operation on a page next to the selected page;
performing the MSB program operation on even-numbered memory cells included in the next page after performing the MSB program operation on odd-numbered memory cells included in the next page.

14. The method of claim 13, wherein the page is a group of memory cells coupled to an identical word line.

15. A method of operating a semiconductor device, comprising:
performing a least significant bit (LSB) program operation on a selected memory cell block;
performing a most significant bit (MSB) program operation on even-numbered memory cells included in a page selected among a plurality of pages included in the selected memory cell block;
performing the MSB program operation on odd-numbered memory cells included in the selected page;
performing the MSB program operation on odd-numbered memory cells included in a page next to the selected page; and
performing the MSB program operation on even-numbered memory cells included in the next page.

16. The method of claim 15, wherein the page is a group of memory cells coupled to an identical word line.

17. A semiconductor device, comprising:
a memory cell array configured to comprise memory cell blocks and flag cell blocks comprising a plurality of pages;
a row decoder coupled to word lines of the memory cell array;
a voltage generator configured to generate driving voltages and transfer the driving voltages to the row decoder;
page buffers coupled to bit lines of the memory cell array; and
a controller configured to control the row decoder, the voltage generator, and the page buffers in order to program all selected memory cells included in a memory cell block selected among the memory cell blocks in such a way as to sequentially program even-numbered memory cells and odd-numbered memory cells included in a selected page of pages included in the selected memory cell block and then sequentially program odd-numbered memory cells and even-numbered memory cells included in a page next to the selected page.

18. The semiconductor device of claim 17, wherein the controller is configured to further control the row decoder, the voltage generator, and the page buffers in order to read memory cells coupled to the next word line, and read memory cells coupled to the selected word line by using a first read voltage when the memory cells coupled to the next word line are not programmed and read the memory cells coupled to the selected word line by using a second read voltage higher than the first read voltage when the memory cells coupled to the next word line are programmed.

19. The semiconductor device of claim 18, wherein when the memory cells coupled to the next word line are read, the controller is configured to control the row decoder, the voltage generator, and the page buffers in order to read the memory cells coupled to the next word line by using the first read voltage and determine whether a least significant bit (LSB) program operation or a most significant bit (MSB) program operation has been performed on the memory cells coupled to the next word line.

20. The semiconductor device of claim 19, wherein the controller is configured to control the row decoder, the voltage generator, and the page buffers in order to read the memory cells coupled to the selected word line by using the second read voltage if, as a result of the determination, it is determined that the LSB program operation has been performed on the memory cells coupled to the next word line and read the memory cells coupled to the selected word line by using a third read voltage higher than the second read voltage if, as a result of the determination, it is determined that the MSB program operation has been performed on the memory cells coupled to the next word line.
